(19) United States
(12) Patent Application Publication
(10) Pub. No.: US 2004/0126944 A1
(43) Pub. Date: Jul. 1, 2004

(54) Methods for forming interfacial layer for deposition of high-k dielectrics

(76) Inventors: Antonio Luis Pacheco Rotondaro, Dallas, TX (US); Douglas E. Mercer, Richardson, TX (US); Luigi Colombo, Dallas, TX (US)

Correspondence Address: TEXAS INSTRUMENTS INCORPORATED, P O BOX 655474, M/S 3999, DALLAS, TX, 75265

(21) Appl. No.: 10/335,567

(22) Filed: Dec. 31, 2002

(51) Int. Cl. H01L 21/336

(52) U.S. Cl. 438/197

(57) ABSTRACT

Methods are provided for fabricating a transistor gate structure in a semiconductor device, comprising growing an interface oxide layer to a thickness of about 18 Å or less over a semiconductor body using an oxidant comprising N₂O and hydrogen or NO and hydrogen at a temperature of about 800 degrees C. or more and a pressure of about 200 Torr or less. A high-k dielectric layer is formed over the interface oxide layer, and a gate contact layer is formed over the high-k dielectric layer. The gate contact layer, the high-k dielectric layer, and the interface oxide layer are then patterned to form a transistor gate structure.

### FIELD OF INVENTION

This invention relates generally to semiconductor devices and more particularly to methods for fabricating transistor gate structures having high-k gate dielectrics in the manufacture of semiconductor devices.

### BACKGROUND OF THE INVENTION

Field effect transistors (FETs) are widely used in the electronics industry for switching, amplification, filtering, and other tasks related to both analog and digital electrical signals. Most common among these are metal-oxide-semiconductor field-effect transistors (MOSFETs), wherein a metal or polysilicon gate contact is energized to create an electric field in a channel region of a semiconductor body, by which current is allowed to conduct between a source region and a drain region of the semiconductor body. The source and drain regions are typically formed by adding dopants to targeted regions on either side of the channel region in a semiconductor substrate. A gate dielectric, such as silicon dioxide (SiO₂), is formed over the channel region, and a gate contact (e.g., metal or doped polysilicon) is formed over the gate dielectric, where the gate dielectric and gate contact materials are patterned to form a gate structure overlying the channel region of the substrate.

The gate dielectric is an insulator material, which prevents large currents from flowing from the gate into the channel when a voltage is applied to the gate contact, while allowing such an applied gate voltage to set up an electric field in the channel region in a controllable manner. A continuing trend in the manufacture of semiconductor products is toward a steady reduction in electrical device feature size (scaling), together with improvement in device performance in terms of device switching speed and power consumption. New materials and processes have been developed and employed in silicon process technology to accommodate device scaling, including the ability to pattern and etch smaller device features. Recently, however, electrical and physical limitations have been reached in the thickness of gate dielectrics formed of SiO₂.

FIG. 1A illustrates a conventional CMOS device 2 with PMOS and NMOS transistor devices 4 and 6, respectively, formed in or on a silicon substrate 8. Isolation structures 10 are formed to separate and provide electrical isolation of the individual devices 4 and 6 from other devices and from one another. The substrate 8 is lightly doped p-type silicon with an n-well 12 formed therein under the PMOS transistor 4. The PMOS device 4 includes two laterally spaced p-doped source/drain regions 14a and 14b with a channel region 16 located therebetween in the n-well 12. A gate is formed over the channel region 16 comprising an SiO₂ gate dielectric 20 overlying the channel 16 and a conductive polysilicon gate contact structure 22 formed over the gate dielectric 20. The NMOS device 6 includes two laterally spaced n-doped source/drain regions 24a and 24b outlying a channel region 26 in the substrate 8 with a gate formed over the channel region 26 comprising an SiO₂ gate dielectric layer 30 and a polysilicon gate contact 32, where the gate dielectrics 20 and 30 may be patterned from the same oxide layer.

Typical CMOS production processing has thusfar not adopted high-k gate dielectric layers, although such layers are being studied. Instead, the gate dielectric layers 20 and 30 of FIG. 1A are typically formed through thermal oxidation of the silicon substrate 8 to form SiO₂. Referring to the NMOS device 6, the resistivity of the channel 26 may be controlled by the voltage applied to the gate contact 32, by which changing the gate voltage changes the amount of current through channel 26. The gate contact 32 and the channel 26 are separated by the SiO₂ gate dielectric 30, which is an insulator. Thus, little or no current flows between the gate contact 32 and the channel 26, although “tunneling” current is observed with thin dielectrics. However, the gate dielectric 30 allows the gate voltage at the contact 32 to induce an electric field in the channel 26, by which the channel resistance can be controlled by the applied gate voltage.

MOSFET devices produce an output signal proportional to the ratio of the width over the length of the channel, where the channel length is the physical distance between the source/drain regions (e.g., between regions 24a and 24b in the device 6) and the width runs perpendicular to the length (e.g., perpendicular to the page in FIG. 1A). Thus, scaling the NMOS device 6 to make the width narrower may reduce the device output current. Previously, this characteristic has been accommodated by decreasing the thickness of gate dielectric 30, thus bringing the gate contact 32 closer to the channel 26 for the device 6 of FIG. 1A. Making the gate dielectric layer 30 thinner, however, has other effects, which may lead to performance tradeoffs, particularly where the gate dielectric 30 is SiO₂.

One shortcoming of a thin SiO₂ gate dielectric 30 is large gate tunneling leakage currents due to direct tunneling through the oxide 30. This problem is exacerbated by conventional limitations in the ability to deposit such thin films with uniform thickness. Also, a thin SiO₂ gate dielectric layer 30 provides a poor diffusion barrier to dopants, for example, causing high boron dopant penetration into the underlying channel region 26 during fabrication of the source/drain regions 24a and 24b. Furthermore, uniform SiO₂ layers currently can only be grown down to about 8 Å or more.

Consequently, recent efforts involving MOSFET device scaling have focused on alternative dielectric materials which can be formed in a thicker layer than scaled silicon dioxide layers and yet still produce the same field effect performance. These materials are often referred to as high-k materials because their dielectric constants are greater than that of SiO₂. The relative performance of such high-k materials is often expressed as equivalent oxide thickness (EOT), because the alternative material layer may be thicker, while still providing the equivalent electrical effect of a much thinner layer of SiO₂.

In one approach, such high-k dielectrics are typically deposited directly over a silicon substrate to form a gate dielectric layer of about 50 Å. The performance and reliability of the resulting transistors, however, is dependent upon the quality of the interface between the high-k dielectric material and the underlying silicon. Referring to FIG. 1B, one proposed alternative structure is illustrated, in which a high-k gate dielectric material 30a is used to form a gate dielectric layer 30′ in an NMOS device 6′. A conductive polysilicon gate contact structure 32′ is then formed over the high-k dielectric layer 30a. However, the alternative gate dielectric materials explored thusfar typically include oxygen components, and are often deposited using oxidizing deposition techniques, such as chemical vapor deposition (CVD), atomic layer deposition (ALD), or sputtering processes.

Thus, in forming the high-k dielectric layer 30a, the upper surface of the silicon substrate 8 oxidizes, forming an unintended low quality oxide layer 30b between the substrate 8 and the high-k material 30a. The presence of this interfacial oxide layer 30b increases the effective oxide thickness, reducing the effectiveness of the alternative gate dielectric approach. In addition, the interface 30b generally has uncompleted bonds, that act as interface charging centers, causing interface states. The high density of such interface states in the low quality oxide 30b results in carrier mobility degradation in operation of the transistor 6′, where the higher the density of the interface states, the more the resulting mobility degradation. In FIG. 1B, for example, the unintended oxide 30b (e.g., SiO or SiO₂) typically has defects, and may include carbon, chlorine or hydroxyl groups.

Other approaches involve forming a chemical oxide (e.g., UV-ozone oxide or UV-O₃) prior to depositing the high-k material 30a, to try to mitigate the mobility degradation problem. Such chemical oxides are typically grown at low temperatures in a hydrogen peroxide H₂O₂ wet chemical. While these chemical oxides are better than unintended thermal oxides (e.g., layer 30b in FIG.1B), there is a need for better mobility than that which can be achieved with chemical oxides. Therefore, there is a need for improved gate fabrication techniques by which high quality interfaces can be achieved between the underlying silicon and deposited high-k dielectrics.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later. The invention relates to methods for forming gate dielectric structures for MOSFET devices, wherein a high quality interface oxide layer is grown to a thickness of about 18 Å or less over a semiconductor body using an oxidant comprising N₂O or NO and hydrogen at high temperature and low pressure. A high-k dielectric layer is then formed over the interface oxide layer with the interface oxide acting as a nucleation layer for the high-k dielectric material, and a gate contact layer is formed over the high-k dielectric layer. The gate contact layer, the high-k dielectric layer, and the interface oxide layer are then patterned to form a transistor gate structure.

In one aspect of the invention, a method is provided for fabricating a transistor gate structure in a semiconductor device, comprising growing an interface oxide layer to a thickness of about 7 Å or less over a semiconductor body using an oxidant comprising hydrogen and N₂O or NO. The interface oxide is grown at a temperature of about 800 degrees C. or more and a pressure of about 200 Torr or less. The method further comprises forming a high-k dielectric layer over the interface oxide layer, forming a gate contact layer over the high-k dielectric layer, and patterning the gate contact layer, the high-k dielectric layer, and the interface oxide layer to form a transistor gate structure.

In another aspect of the invention, the interface oxide layer is grown to a thickness of about 18 Å or less using an oxidant comprising NO and hydrogen at a temperature of about 800 degrees C. or more and a pressure of about 200 Torr or less. In yet another aspect of the invention, the interface oxide layer is grown to a thickness of about 18 Å or less over a semiconductor body using an oxidant comprising N₂O or NO and hydrogen at a temperature of about 800 degrees C. or more and a pressure of more than about 1 Torr and about 200 Torr or less.

To the accomplishment of the foregoing and related ends, the following description and annexed drawings set forth in detail certain illustrative aspects and implementations of the invention. These are indicative of but a few of the various ways in which the principles of the invention may be employed. Other aspects, advantages and novel features of the invention will become apparent from the following detailed description of the invention when considered in conjunction with the drawings.

### BRIEF DESCRIPTION OF THE DRAWINGS

FIG. 1A is a partial side elevation view in section illustrating a conventional semiconductor device with NMOS and PMOS transistors;

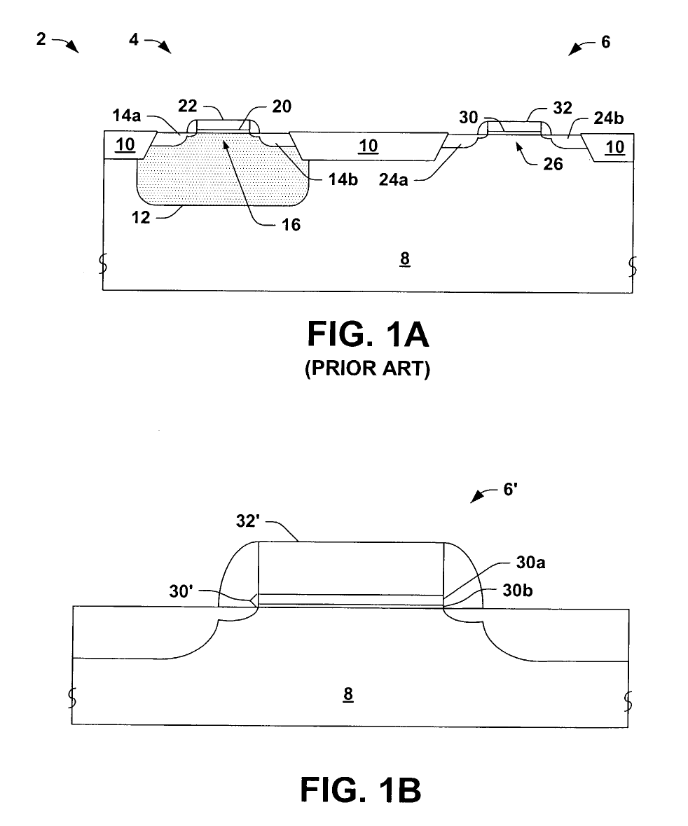

FIG. 1B is a partial side elevation view in section illustrating an unintended low quality interfacial layer in a proposed gate structure;

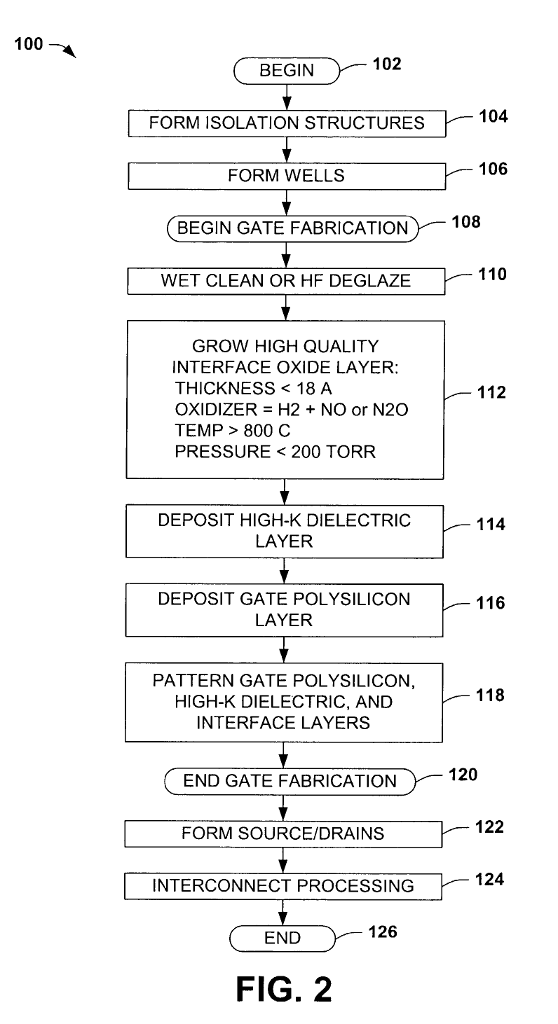

FIG. 2 is a flow diagram illustrating an exemplary method in accordance with the present invention; and

FIGS. 3-8 are partial side elevation views in section illustrating an exemplary semiconductor device being processed at various stages of manufacturing in accordance with various aspects of the invention.

### DETAILED DESCRIPTION OF THE INVENTION

One or more implementations of the present invention will now be described with reference to the attached drawings, wherein like reference numerals are used to refer to like elements throughout. The invention relates to methods for fabricating gate structures in a semiconductor device, which may be employed in association with any type of semiconductor body, including silicon or other semiconductor substrates, as well as silicon or other semiconductor layers deposited over an insulator in an SOI device.

In addition, the invention may be used in conjunction with any type of high-k dielectric materials. Such high-k materials may include, but are not limited to binary metal oxides including aluminum oxide (Al₂O₃), zirconium oxide (ZrO₂), hafnium oxide (HfO₂), lanthanum oxide (La₂O₃), yttrium oxide (Y₂O₃), titanium oxide (TiO₂), as well as their silicates and aluminates; metal oxynitrides including aluminum oxynitride (AlON), zirconium oxynitride (ZrON), hafnium oxynitride (HfON), lanthanum oxynitride (LaON), yttrium oxynitride (YON), as well as their silicates and aluminates such as ZrSiON, HfSiON, LaSiON, YsiON etc.; and perovskite-type oxides including a titanate system material such as barium titanate, strontium titanate, barium strontium titanate (BST), lead titanate, lead zirconate titanate, lead lanthanum zirconate titanate, barium lanthanum titanate, barium zirconium titanate; a niobate or tantalate system material such as lead magnesium niobate, lithium niobate, lithium tantalate, potassium niobate, strontium aluminum tantalate and potassium tantalum niobate; a tungsten-bronze system material such as barium strontium niobate, lead barium niobate, barium titanium niobate; and Bi-layered perovskite system material such as strontium bismuth tantalate, bismuth titanate as are known in the art.

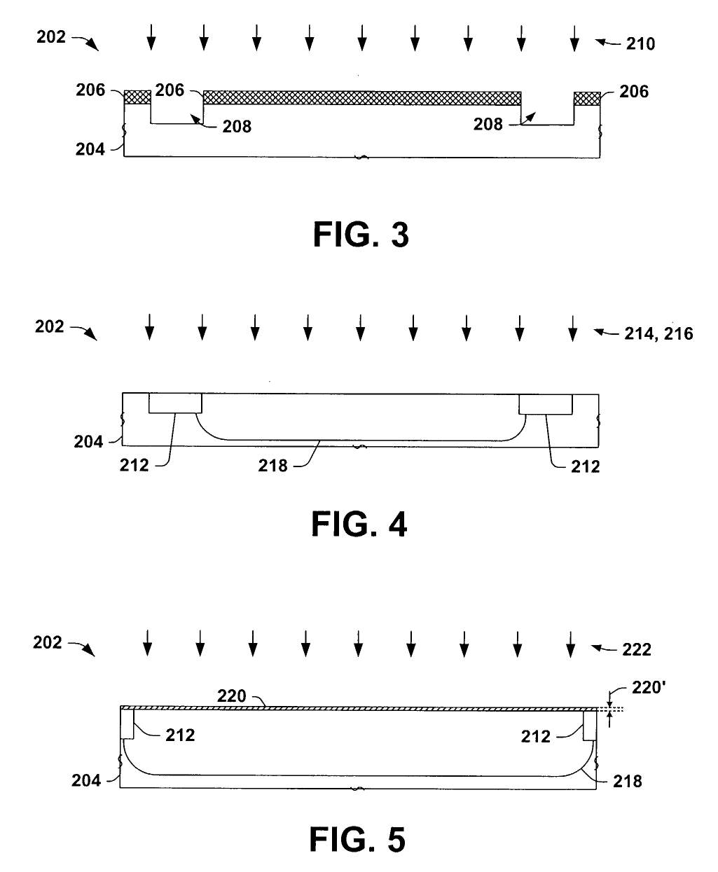

Referring initially to FIG. 2, a flow diagram illustrates an exemplary method 100 for processing semiconductor devices, including fabrication of transistor gate structures in accordance with the present invention. Although the method 100 and other methods herein are illustrated and described below as a series of acts or events, it will be appreciated that the present invention is not limited by the illustrated ordering of such acts or events. For example, some acts may occur in different orders and/or concurrently with other acts or events apart from those illustrated and/or described herein, in accordance with the invention. In addition, not all illustrated steps may be required to implement a methodology in accordance with the present invention. In addition, the methods according to the present invention may be implemented in association with the formation and/or processing of structures illustrated and described herein as well as in association with other structures not illustrated.

Beginning at 102, the method 100 comprises forming isolation structures at 104, such as STI or LOCOS oxide isolation structures in a semiconductor body. At 106, one or more wells (e.g., n-wells and/or p-wells) may be formed in the semiconductor body, according to known implantation and/or diffusion techniques. At 108, gate fabrication begins, where a wet clean or a HF deglaze may be optionally performed at 110 to clean a top surface of the semiconductor body before growing the high quality interface oxide layer. The precleaning at 110 may be employed for removal of any thin dielectric layers from the silicon body, such as silicon oxide (SiO), silicon nitride (SiN), or silicon oxynitride (SiON). For removing SiO, wet cleaning operations can be performed at 110, or a dilute HF solution may be employed to deglaze the semiconductor body. One example of such an HF deglaze involves dipping the semiconductor in a 1:100 volume dilution of 49% HF at room temperature for a duration that is adequate to completely remove any SiO from the surface. In another example, a dry process is employed comprising a mixture of anhydrous HF and isopropyl-alcohol to remove SiO.

At 112, a high quality oxide interface layer is grown over the semiconductor body using an oxidant comprising N₂O and hydrogen or NO and hydrogen at a temperature of about 800 degrees C. or more and a pressure of about 200 Torr or less. While not wishing to be tied to any particular theory, the use of high temperatures at 112 is believed to reduce the interface state density and hence to reduce mobility degradation in the finished transistor devices. The reduced pressure and the employment of hydrogen in the oxidant is believed to facilitate controlled growth and uniformity in the ultra-thin interface oxide, wherein the oxide interface layer may be grown to a thickness of about 18 Å or less at 112.

At 114 a high-k dielectric layer is formed over the interface oxide layer, comprising any appropriate high-k dielectric material, such as those mentioned above. The high-k dielectric layer may be formed at 114 using known deposition techniques, such as chemical vapor deposition (CVD), atomic layer deposition (ALD), or sputtering processes, where the interface oxide layer formed at 112 operates as a high quality nucleation layer for the high-k deposition at 114. The high-k dielectric might be annealed after deposition to heal bulk defects and/or complete its stoichiometry. A conductive metal or polysilicon gate contact layer is then formed at 116, for example, by deposition of polysilicon over the high-k material, after which the gate contact layer, the high-k dielectric layer, and the interface oxide layer are patterned at 118 to form a transistor gate structure, where the gate fabrication ends at 120. At 122, source/drain regions of the semiconductor body are provided with appropriate n or p type dopants through implantation or diffusion, and interconnect processing is performed at 124 according to known interconnect techniques, before the method 100 ends at 126. In an alternate approach, the polysilicon gate contact layer may be initially patterned without patterning the gate dielectric, where the source/drain regions are implanted through the gate dielectric, and the high-k dielectric and interface oxide layers are patterned later.

In one implementation of the invention, the growth of the high quality interface oxide at 112 comprises formation of SiO₂ to a thickness of about 7 Å or less, such as about 1 monolayer to about 7 Å, preferably about 1 monolayer. The resulting interface oxide thickness will be within about one monolayer of SiO₂ of these values, where one monolayer of SiO₂ is believed to be about 2 Å thick. The oxidant employed during the interface oxide growth at 112 in this implementation preferably comprises NO and hydrogen, although N₂O and hydrogen may alternatively be used. In addition, the pressure is controlled during growth of the interface oxide layer to about 200 Torr or less, preferably more than about 1 Torr and about 50 Torr or less in one example. Moreover, the temperature is relatively high in the oxide growth at 112, for example, about 800 degrees C. or more, preferably about 900 degrees C. or more and about 1050 degrees C. or less in one example. The above implementation provides a high quality interface oxide layer at 112, with or without a wet clean or HF deglaze precleaning act at 110, wherein the precleaning at 110 may advantageously facilitate reduction in interface states in the finished product.

In another implementation of the invention, an interface oxide layer is grown at 112 to a thickness of about 18 Å or less over a semiconductor body using an oxidant comprising NO and hydrogen at a temperature of about 800 degrees C. or more and a pressure of about 200 Torr or less. In this implementation, the high quality interface oxide is formed over the semiconductor body to a thickness of about 10 Å or less, such as about 1 monolayer to about 7 Å, preferably about 1 monolayer. The pressure is preferably controlled to more than about 1 Torr and about 50 Torr or less and the temperature is controlled to about 900 degrees C. or more and about 1050 degrees C. or less in one example. As with the previous example, this implementation provides a high quality interface oxide layer at 112, with or without a wet clean or HF deglaze operation at 110 to clean a top surface of the semiconductor body before growing the interface oxide layer.

In still another exemplary implementation of the invention, the interface oxide layer is grown at 112 to a thickness of about 18 Å or less using an oxidant comprising N₂O or NO and hydrogen at a temperature of about 800 degrees C. or more and a pressure of more than about 1 Torr and about 200 Torr or less. In one example of this implementation, the high quality interface oxide is grown to a thickness of about 7 Å or less, such as about 1 monolayer to about 7 Å, preferably about 1 monolayer. In this implementation, the oxidant is preferably NO and hydrogen, although N₂O and hydrogen may alternatively be used. In one example, the pressure is controlled to be more than about 1 Torr and about 20 Torr or less, and the temperature is controlled to about 900 degrees C. or more and about 1050 degrees C. or less, where a wet clean or HF deglaze may, but need not, be employed at 110.

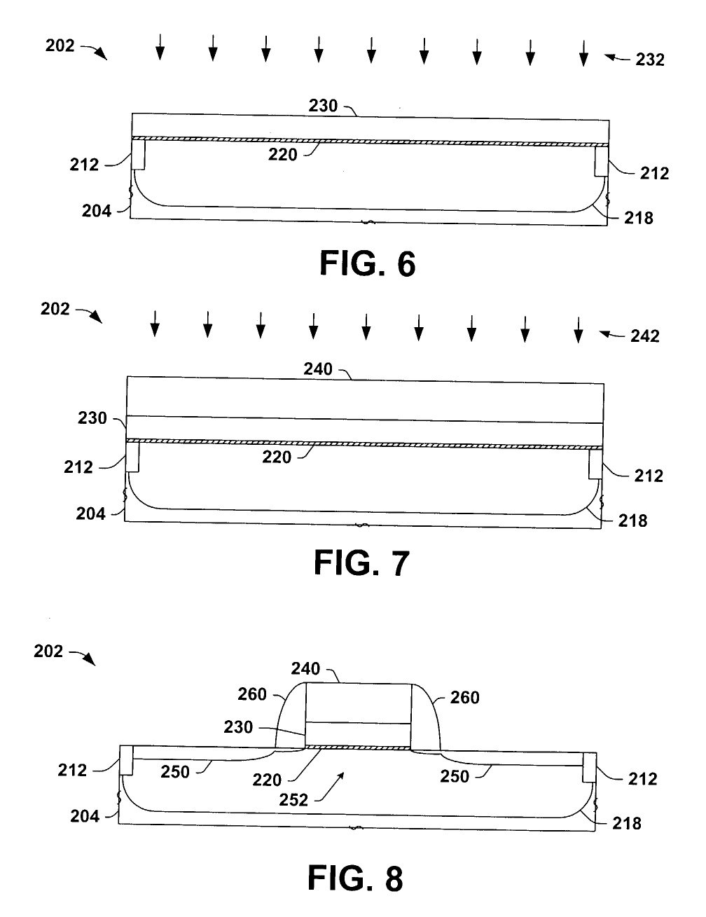

Referring now to FIGS. 3-8, processing of an exemplary semiconductor device 202 is illustrated at various stages of manufacturing in accordance with various aspects of the invention to fabricate transistor gate structures therein. The device 202 comprises a wafer having a semiconductor body 204 therein, such as a silicon substrate or other semiconductor substrate, or a layer of silicon or other semiconductor deposited over an insulator in an SOI device wafer. In the illustrated example, the semiconductor body 204 is a lightly doped p-type silicon substrate.

In FIGS. 3 and 4, isolation structures (e.g., SiO₂ field oxide (FOX) or shallow trench isolation (STI) structures) are initially formed in the body 204 to separate and provide electrical isolation between active areas in the body 204. An isolation mask 206 is formed over the device 202 in FIG. 3 and a trench etch process 210 is performed to form isolation trenches 208 in isolation regions of the semiconductor body 204. The trenches 208 are then filled in FIG. 4 with dielectric material via a deposition process 214 and the device 202 is planarized via a CMP process 216 to leave STI type dielectric isolation structures 212, for example, SiO₂. One or more p and/or n-type wells are then formed in the semiconductor body 204, including an n-well 218, as illustrated in FIG. 4, and an optional wet clean or HF deglaze operation (not shown) may be performed to clean the top surface of the semiconductor body 204.

In FIG. 5, gate fabrication processing begins with the growth of a high quality SiO₂ interface oxide layer 220 over the semiconductor body 204 via a high temperature, low pressure oxidation process 222. The oxide interface layer 220 has a thickness 220′ of about 18 Å or less, which may be about 10 Å or less in one example, about 7 Å or less in a second example, about 1 monolayer to about 7 Å, or preferably about 1 monolayer in another example. The oxidation process 222 is performed for a duration of about one second or less, up to about 1 minute at a temperature of about 800 degrees C. or more, such as about 950 degrees C. or more and about 1050 degrees C. or less in one example. Further, the pressure is controlled in the process 222 to be about 200 Torr or less, such as more than about 1 Torr and about 50 Torr or less in one example, and more than about 1 Torr and about 20 Torr or less in another example.

In FIG. 6, a high-k dielectric layer 230 is formed over the interface oxide layer via a deposition process 232 (e.g., CVD, ALD, or sputtering), where the high-k dielectric layer 230 comprises any appropriate high-k dielectric material, such as those mentioned above. During the high-k deposition 232 in FIG. 6, the interface oxide layer 220 operates as a high quality nucleation layer for deposition of the high-k material 230. The high-k dielectric might be annealed to heal bulk defects and/or to complete its stoichiometry. A gate contact layer 240 such as polysilicon is then deposited in FIG. 7 over the high-k material via a deposition process 242. In FIG. 8, the gate contact layer 240, the high-k dielectric layer 230, and the interface oxide layer 220 are patterned to form a transistor gate structure. Source/drain regions 250 are doped with p-type impurities on either side of a channel region 252 in the semiconductor body 204, and sidewall spacers 260 are formed along the sides of the patterned layers 220, 230, and 240 as illustrated in FIG. 8. Thereafter, interconnect processing (not shown) is performed to interconnect the illustrated MOS type transistor and other electrical components in the device 202.

Although the invention has been illustrated and described with respect to one or more implementations, equivalent alterations and modifications will occur to others skilled in the art upon the reading and understanding of this specification and the annexed drawings. In particular regard to the various functions performed by the above described components (assemblies, devices, circuits, systems, etc.), the terms (including a reference to a “means”) used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising.”

What is claimed is:

1. A method of fabricating a transistor gate structure in a semiconductor device, comprising:
growing an interface oxide layer to a thickness of about 7 Å or less over a semiconductor body using an oxidant comprising N₂O and hydrogen or NO and hydrogen at a temperature of about 800 degrees C. or more and a pressure of about 200 Torr or less;
forming a high-k dielectric layer over the interface oxide layer;
forming a gate contact layer over the high-k dielectric layer; and
patterning the gate contact layer, the high-k dielectric layer, and the interface oxide layer to form a transistor gate structure.

2. The method of claim 1, wherein growing the interface oxide layer comprises growing an SiO₂ interface oxide layer to a thickness of about 1 monolayer or more and about 7 Å or less over the semiconductor body.

3. The method of claim 1, wherein growing the interface oxide layer comprises growing an SiO₂ interface oxide layer to a thickness of about 1 monolayer over the semiconductor body.

4. The method of claim 1, wherein growing the interface oxide layer comprises growing an SiO₂ interface oxide layer using an oxidant comprising NO and hydrogen.

5. The method of claim 4, wherein growing the interface oxide layer comprises growing the SiO₂ interface oxide layer at a pressure of more than about 1 Torr and about 50 Torr or less.

6. The method of claim 5, wherein growing the interface oxide layer comprises growing the SiO₂ interface oxide layer at a temperature of about 900 degrees C. or more and about 1050 degrees C. or less.

7. The method of claim 5, further comprising performing a wet clean operation or an HF deglaze operation to clean a top surface of the semiconductor body before growing the interface oxide layer.

8. The method of claim 1, wherein growing the interface oxide layer comprises growing an SiO₂ interface oxide layer at a pressure of more than about 1 Torr and about 50 Torr or less.

9. The method of claim 1, wherein growing the interface oxide layer comprises growing an SiO₂ interface oxide layer at a temperature of about 900 degrees C. or more and about 1050 degrees C. or less.

10. The method of claim 1, further comprising performing a wet clean operation or an HF deglaze operation to clean a top surface of the semiconductor body before growing the interface oxide layer.

11. A method of fabricating a transistor gate structure in a semiconductor device, comprising:
growing an interface oxide layer to a thickness of about 18 Å or less over a semiconductor body using an oxidant comprising NO and hydrogen at a temperature of about 800 degrees C. or more and a pressure of about 200 Torr or less;
forming a high-k dielectric layer over the interface oxide layer;
forming a gate contact layer over the high-k dielectric layer; and
patterning the gate contact layer, the high-k dielectric layer, and the interface oxide layer to form a transistor gate structure.

12. The method of claim 11, wherein growing the interface oxide layer comprises growing an SiO₂ interface oxide layer to a thickness of about 10 Å or less over the semiconductor body.

13. The method of claim 12, wherein growing the interface oxide layer comprises growing the SiO₂ interface oxide layer to a thickness of about 1 monolayer or more and about 7 Å or less over the semiconductor body.

14. The method of claim 13, wherein growing the interface oxide layer comprises growing the SiO₂ interface oxide layer to a thickness of about 1 monolayer over the semiconductor body.

15. The method of claim 13, wherein growing the interface oxide layer comprises growing the SiO₂ interface oxide layer at a pressure of more than about 1 Torr and about 50 Torr or less.

16. The method of claim 13, wherein growing the interface oxide layer comprises growing the SiO₂ interface oxide layer at a temperature of about 900 degrees C. or more and about 1050 degrees C. or less.

17. The method of claim 13, further comprising performing a wet clean operation or an HF deglaze operation to clean a top surface of the semiconductor body before growing the interface oxide layer.

18. The method of claim 11, wherein growing the interface oxide layer comprises growing an SiO₂ interface oxide layer at a pressure of more than about 1 Torr and about 50 Torr or less.

19. The method of claim 11, wherein growing the interface oxide layer comprises growing an SiO₂ interface oxide layer at a temperature of about 900 degrees C. or more and about 1050 degrees C. or less.

20. The method of claim 11, further comprising performing a wet clean operation or an HF deglaze operation to clean a top surface of the semiconductor body before growing the interface oxide layer.

21. A method of fabricating a transistor gate structure in a semiconductor device, comprising:
growing an interface oxide layer to a thickness of about 18 Å or less over a semiconductor body using an oxidant comprising N₂O and hydrogen or NO and hydrogen at a temperature of about 800 degrees C. or more and a pressure of more than about 10 Torr and about 200 Torr or less;
forming a high-k dielectric layer over the interface oxide layer;
forming a gate contact layer over the high-k dielectric layer; and
patterning the gate contact layer, the high-k dielectric layer, and the interface oxide layer to form a transistor gate structure.

22. The method of claim 21, wherein growing the interface oxide layer comprises growing an SiO₂ interface oxide layer to a thickness of about 1 monolayer or more and about 7 Å or less over the semiconductor body.

23. The method of claim 22, wherein growing the interface oxide layer comprises growing the SiO₂ interface oxide layer to a thickness of about 1 monolayer over the semiconductor body.

24. The method of claim 21, wherein growing the interface oxide layer comprises growing an SiO₂ interface oxide layer using an oxidant comprising NO and hydrogen.

25. The method of claim 24, wherein growing the interface oxide layer comprises growing the SiO₂ interface oxide layer at a pressure of more than about 10 Torr and about 20 Torr or less.

26. The method of claim 25, wherein growing the interface oxide layer comprises growing the SiO₂ interface oxide layer at a temperature of about 900 degrees C. or more and about 1050 degrees C. or less.

27. The method of claim 25, further comprising performing a wet clean operation or an HF deglaze operation to clean a top surface of the semiconductor body before growing the interface oxide layer.

28. The method of claim 21, wherein growing the interface oxide layer comprises growing an SiO₂ interface oxide layer at a pressure of more than about 10 Torr and about 20 Torr or less.

29. The method of claim 28, wherein growing the interface oxide layer comprises growing the SiO₂ interface oxide layer at a temperature of about 900 degrees C. or more and about 1050 degrees C. or less.

30. The method of claim 28, further comprising performing a wet clean operation or an HF deglaze operation to clean a top surface of the semiconductor body before growing the interface oxide layer.

31. The method of claim 21, wherein growing the interface oxide layer comprises growing the SiO₂ interface oxide layer at a temperature of about 900 degrees C. or more and about 1050 degrees C. or less.

32. The method of claim 21, further comprising performing a wet clean operation or an HF deglaze operation to clean a top surface of the semiconductor body before growing the interface oxide layer.
